(19) United States
(12) Patent Application Publication
(10) Pub. No.: US 2015/0091172 A1
(43) Pub. Date: Apr. 2, 2015

(54) PORE SEALING TECHNIQUES FOR POROUS LOW-K DIELECTRIC INTERCONNECT

(71) Applicant: Taiwan Semiconductor Manufacturing Co., Ltd., Hsin-Chu (TW)

(72) Inventors: Chung-Chi Ko, Nantou (TW); Pei-Wen Huang, New Taipei City (TW); Chun-Yi Lee, Beipu Township (TW); Kuang-Yuan Hsu, Taichung City (TW); Tze-Liang Lee, Hsinchu (TW)

(73) Assignee: Taiwan Semiconductor Manufacturing Co., Ltd., Hsin-Chu (TW)

(21) Appl. No.: 14/043,279

(22) Filed: Oct. 1, 2013

(51) Int. Cl. H01L 23/532; H01L 21/768; H01L 23/522

(52) U.S. Cl. CPC H01L 23/5329; H01L 23/5226; H01L 21/76814; H01L 21/76843
USPC 257/741; 438/637

(57) ABSTRACT

The present disclosure relates to a method of forming pore sealing layer for porous low-k dielectric interconnects. The method is performed by removing hard mask layer before pore sealing and/or applying pore sealing layer before etching etch stop layer (ESL). These methods at least have advantages that aspect ratio is improved, line distortion introduced by the hard mask layer is avoided, and critical dimension is less affected by pore sealing layer.

### BACKGROUND

As dimensions of monolithic integrated circuit (IC) are scaled down, it is necessary to minimize the dielectric constant of the insulating layer in which the interconnects are formed, so as to reduce interconnect delay and capacitance. For this reason, porous low dielectric constant (low-k) materials are being utilized for advanced technology.

Creating pores in dielectric material introduces problems with the mechanical and electrical integrity of the structures during subsequent processing, for example, chemical penetration, metal diffusion, and etch damage. Therefore, there are numerous approaches in order to seal sidewalls of the low-k dielectric interconnect. Some of the approaches have a deficiency that the etch used to open the bottom of vias can leave polymeric residues or damage an underlying conductive layer, thereby preventing a good electrical contact between the via and the underlying conductive structure.

### BRIEF DESCRIPTION OF THE DRAWINGS

FIGS. 1A-1B illustrate a method for forming an interconnect structure which suffers from some shortcomings.

FIGS. 2A-2C illustrates a method of forming an interconnect structure in accordance with some embodiments.

FIG. 3 illustrates a cross-sectional view of a dual damascene interconnect structure in accordance with some embodiments.

FIGS. 4A-4B illustrate flow diagrams of some embodiments of methods for forming an interconnect structure.

FIGS. 5-13 illustrate cross-sectional views of some embodiments of a method of forming an interconnect structure.

FIG. 14 illustrates a detailed flow diagram of some alternative embodiments of a method for forming a pore sealing layer.

FIGS. 15-22 illustrate cross-sectional views of some alternative embodiments of a substrate upon which a method of pore sealing is performed.

### DETAILED DESCRIPTION

The description herein is made with reference to the drawings, wherein like reference numerals are generally utilized to refer to like elements throughout, and wherein the various structures are not necessarily drawn to scale. In the following description, for purposes of explanation, numerous specific details are set forth in order to facilitate understanding. It will be appreciated that the details of the figures are not intended to limit the disclosure, but rather are non-limiting embodiments. For example, it may be evident, however, to one of ordinary skill in the art, that one or more aspects described herein may be practiced with a lesser degree of these specific details. In other instances, known structures and devices are shown in block diagram form to facilitate understanding.

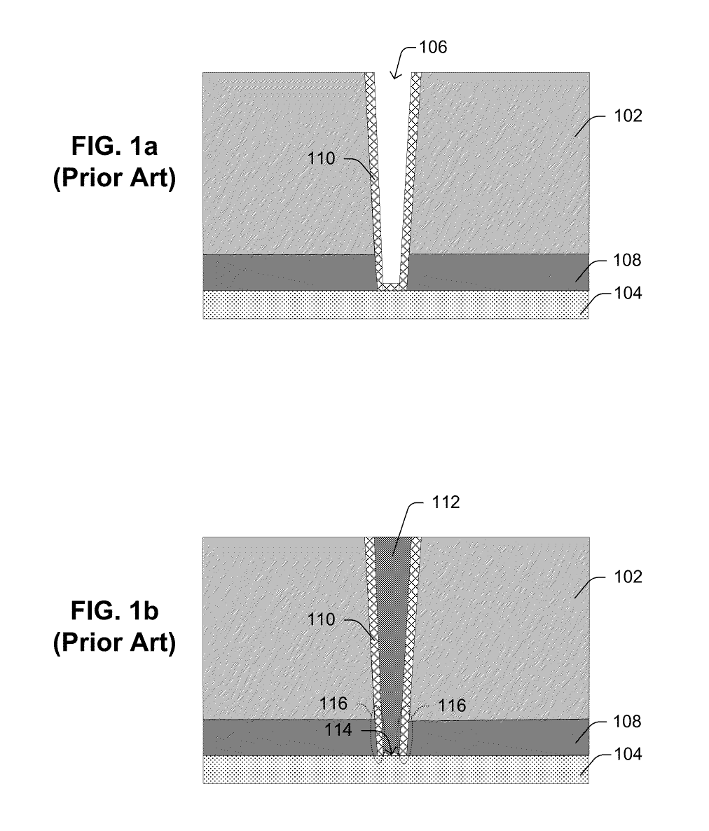

FIG. 1a and FIG. 1b illustrate a technique for forming of an interconnect structure through a porous low-k dielectric which suffers from some shortcomings. In this technique, a porous low-k dielectric layer 102 provides good electrical isolation between a first conductive layer 104 arranged under the low-k dielectric layer 102 and a second conducive layer (not shown) arranged above the low-k dielectric layer 102. To form the desired interconnect structure, an opening 106 is first formed in the low-k dielectric layer 102 and its underlying etch stop layer 108, as shown in FIG. 1a. To avoid a number of potential diffusion and etch issues that can arise from using a porous low-k material, a pore sealing layer 110 is applied to an inner surface of the opening 106. After the pore sealing layer 110 is applied, an etch process is used to remove the pore sealing layer 110 from the bottom of opening 106, and a conductive interconnect structure 112 is formed in the opening 106, as shown in FIG. 1b.

Unfortunately, the pore sealing layer 110 can be difficult to remove from the bottom of opening 106 and/or it may be difficult to achieve good etch selectivity between the pore sealing layer 110 and the underlying conductive layer 104. Hence, in cases where the pore sealing layer 110 is not completely removed, polymeric residues 114 can remain on the upper surface of the underlying conductive layer 104. These polymeric residues 114 can adversely affect via resistance, yield, and interconnect reliability. Further, if the etch used to remove the pore sealing layer 110 is overly aggressive in an attempt to completely remove any polymeric residues 114 and/or is not selective enough, the upper surface of the underlying conductive layer 104 can be damaged, which can also adversely affect via resistance, yield, and interconnect reliability. Also, the thickness of pore seal layer 110, when deposited on the sidewall of the opening (see 116), may tend to “pinch off” the bottom of the opening 106, and thereby affects the critical dimension which becomes important for advanced technology when dimensions are scaled down. If left in place, the pore seal layer 110 can have negative effects on the effective dielectric constant, capacitance and/or the copper resistivity.

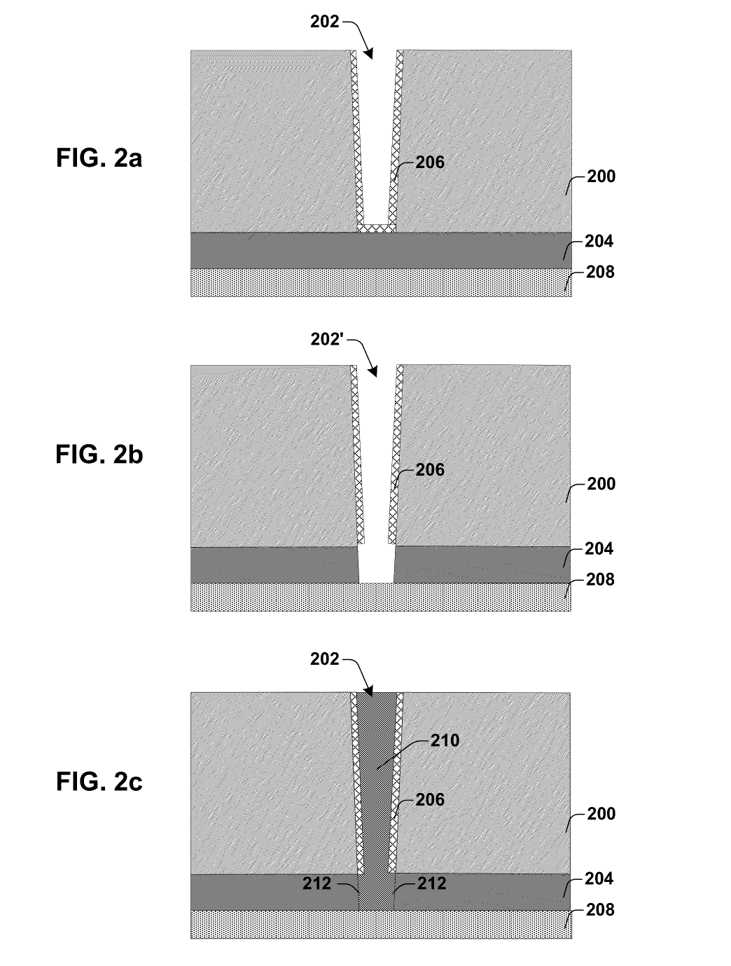

To alleviate these shortcomings, some aspects of the present disclosure provide improved methods for forming interconnect structures in the context of porous low-k dielectrics. FIGS. 2a through 2c show a method for forming an interconnect structure in accordance with some embodiments. In FIG. 2a, an opening 202 is formed in a porous low-k dielectric layer 200, however this opening 202 stops on underlying etch stop layer 204. A pore sealing layer 206 is applied to an inner surface of the opening 202. As shown in FIG. 2b, after the pore sealing layer 206 is applied, an etch process is used to remove pore seal layer 206 from the bottom of opening 202. The etch process also extends the opening 202 so the extended opening 202′ passes through the etch stop layer 204 to expose an underlying conductive layer 208. As shown in FIG. 2c, a conductive material 210 is then formed in the extended opening 202′ to form an interconnect structure, which extends between the lower conductive layer 208 and an upper conductive layer (not shown).

Notably, because the pore sealing layer 206 is formed prior to removal of etch stop layer 204, the pore sealing layer 206 can be removed completely together with a portion of etch stop layer 204 without polymeric residue and without damaging the underlying conductive layer 208. Also, because there is no pore seal layer on the etch stop layer sidewalls 212, the lower portion of the extended opening 202′ is “opened up” relative to previous approaches, thereby giving a larger critical dimension for the conductive interconnect structure 210 to fill in the extended opening 202′, and providing lower resistance and better electrical conductivity.

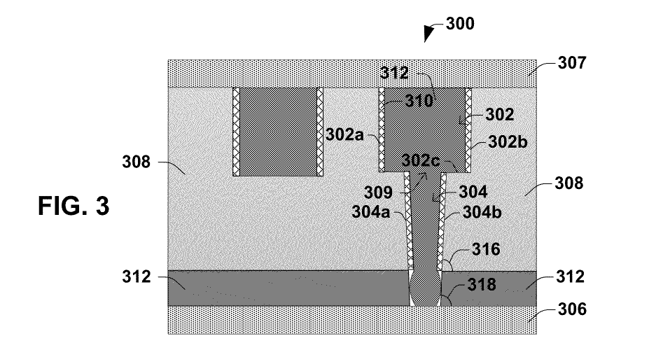

As will be appreciated in more detail herein, the techniques provided herein are also applicable to dual damascene interconnect structures 300, such as shown in FIG. 3. Rather than having a single hole with vertical or continuously tapered sidewalls (e.g., hole 202 as shown in FIG. 2), a dual damascene interconnect structure 300 can include a trench 302 (e.g., a relatively wide upper opening) and a via 304 (a relatively narrow lower opening), which collectively form an opening between a lower conductive layer 306 and an upper conductive layer 307 that surround a porous low-k dielectric layer 308. The trench 302 includes trench sidewalls 302a, 302b and a trench bottom surface 302c, and the via 304 includes an upper region defined by an aperture 309 in the trench bottom surface 302c and via sidewalls 304a, 304b extending downwardly from the trench bottom surface 302c. A pore seal layer 310 is arranged on the trench sidewalls and the via sidewalls but not on the trench bottom surface nor on via bottom surface. The pore seal layer thickness on the trench sidewalls 306a, 306b and the via sidewalls 308a, 308b may be different, caused by the different etching and cleaning steps applied to the trench 302 and via 304. The thickness of the pore seal layer 310 on the trench sidewalls can be either larger or smaller than the thickness of the pore seal layer on the via sidewalls. The pore seal layer 310 is also not on the etch stop layer sidewalls. Similarly, having no pore seal layer on the etch stop sidewalls within opening 310 helps with the critical dimension by keeping the bottom of via opening “opened up”. In order to allow the conductive material 314 to better fill the trench 302 and via 304, the via's sidewalls may form a non-perpendicular angle 316 with regards to low-k dielectric material layer's surface and etch stop layer's surface. This via sidewall angle 316 may be different from the trench's sidewall angle 318 because of the etching and depositing process.

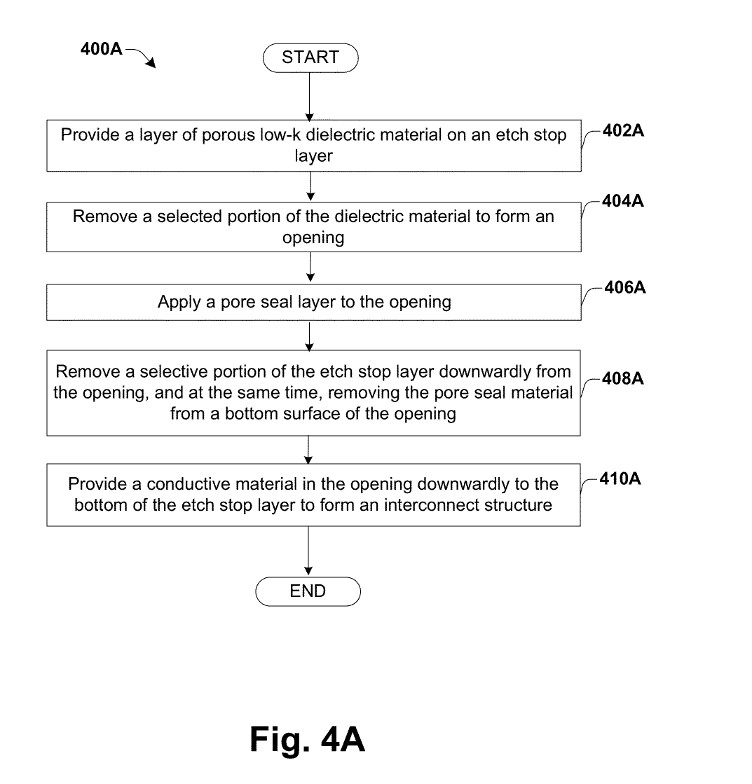

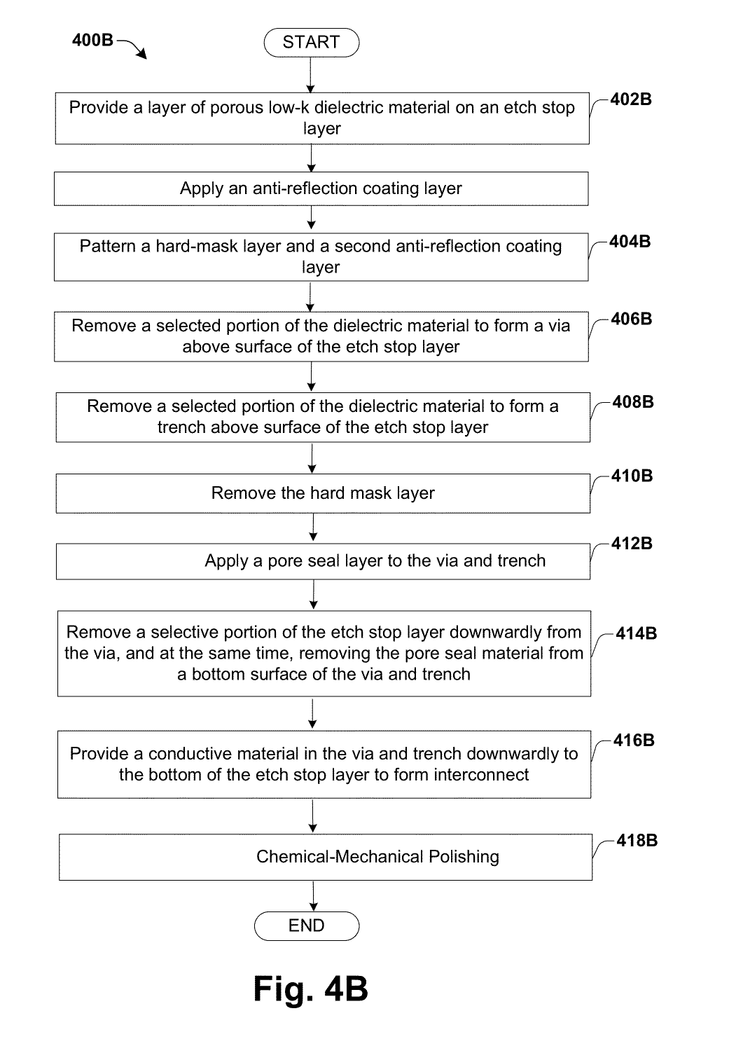

FIG. 4A illustrates a flow diagram of a method 400A of forming an interconnect structure in accordance with some embodiments. While disclosed methods (e.g., methods 400A of FIG. 4A and 400B of FIG. 4B) are illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At 402A, a layer of porous low-k dielectric material is provided onto an etch stop layer. The porous low-k dielectric material with dielectric constant smaller than 2.5 may be utilized for advanced technology, such as 20 node and beyond.

At 404A, one or more openings are formed by removing a selected portion of the dielectric material. These openings can be formed by any method, for example, traditional interconnect etching, typical dual damascene including but not only via-first, trench-first, or double patterning approach.

At 406A, a pore seal layer is applied into the opening. The pore seal layer is not necessarily deposited on the entire exposed surface of the low-k material in the opening. In some embodiments, additional processes including mask patterning and/or removal may be applied prior to 406. Therefore, a portion of the pore seal layer may be applied onto other layers' surface. In some embodiments, the pore seal layer may be deposited by way of a vapor deposition technique (e.g., a chemical vapor deposition(CVD) , a physical vapor deposition (PVD), plasma-enhanced CVD (PECVD), atomic layer deposition (ALD), plasma-enhanced ALD (PEALD), high density plasmas (HDP), or flowable CVD).

At 408A, a selective portion of the etch stop layer is removed downwardly from the opening, at the same time, the pore seal layer on a bottom of the opening is removed.

At 410A, a conductive material is provided in the opening downwardly to the bottom of the etch stop layer to form an interconnect structure.

FIG. 4B illustrates a detailed flow diagram of some embodiments of a method for forming an interconnect structure in accordance with some embodiments. The method 400B improves aspect ratio (AR) and line distortion of the low-k dielectric material by removing hard mask before applying the pore seal layer.

At 402B, the porous low-k material is applied to the etch stop layer (ESL). At 404B, a hard mask layer is patterned on the porous low-k dielectric material. A process of the hard mask patterning can be combined with some additional processes to improve performance.

At 406B and 408B of FIG. 4B, a selective portion of the dielectric material is removed comprising forming a trench in the low-k dielectric material and forming a via in the low-k dielectric material under the trench

At 410B, the hard mask layer is removed. This step helps to decrease the depth of the trench 802 so that aspect ratio is smaller. Also, removing the hard mask layer 602 helps to avoid line distortion of the low-k material in small dimension by removing the compressive stress coming from the hard mask layer.

At 412B, a pore seal layer is applied to the via opening 702 and the trench opening 802. The pore seal layer 208 may comprise oxide, SiC, SiN, SiCN, or dense low-k (SiOCH), for example. A thickness of the pore seal layer 208 can be between 1 to 10 in some embodiments.

At 414B, Liner remove method (LRM) etching and wet cleaning process is applied to remove a selective portion of the etch stop layer downwardly from the via, and at the same time, the pore seal material from a bottom surface of the via and trench is removed.

At 416B, a conductive material 1202 is provided into the via and trench opening downwardly to the bottom of the etch stop layer to form interconnect and chemical-mechanical polish may be applied afterwards for the possible processes next then.

At 418B, a chemical-mechanical polish is applied to remove layers above the porous low-k layer top surface to prepare for the steps next then.

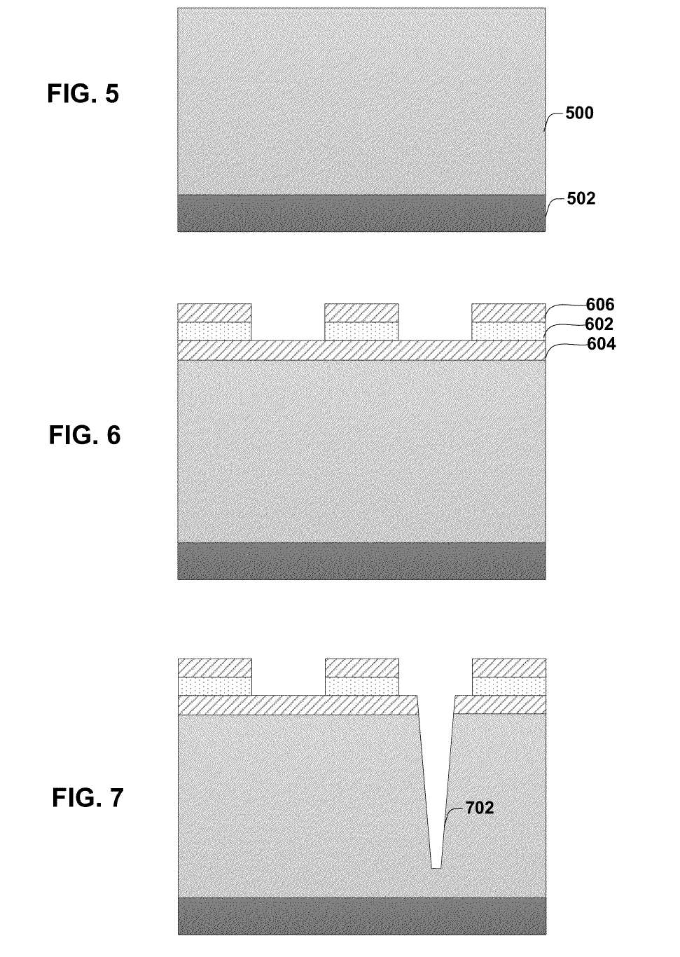

One example of FIG. 4B's method is now described with regards to a series of cross-sectional views as shown in FIGS. 5-12. Although FIGS. 5-12 are described in relation to method 400B, it will be appreciated that the structures disclosed in FIGS. 5-12 are not limited to such a method, but instead may stand alone as a structure.

At FIG. 5, a porous low-k material 500 is applied onto the etch stop layer 502. An underlying conductive layer is not shown in the figure, but is also present as previously illustrated and discussed, for example as shown in FIGS. 2-3.

At FIG. 6, a hard mask 602 is patterned between two anti-reflection coating layers 604 and 606. The anti-reflection coating layers can be nitrogen free anti-reflection coating layer (NFARL). The hard-mask layer can be TiN.

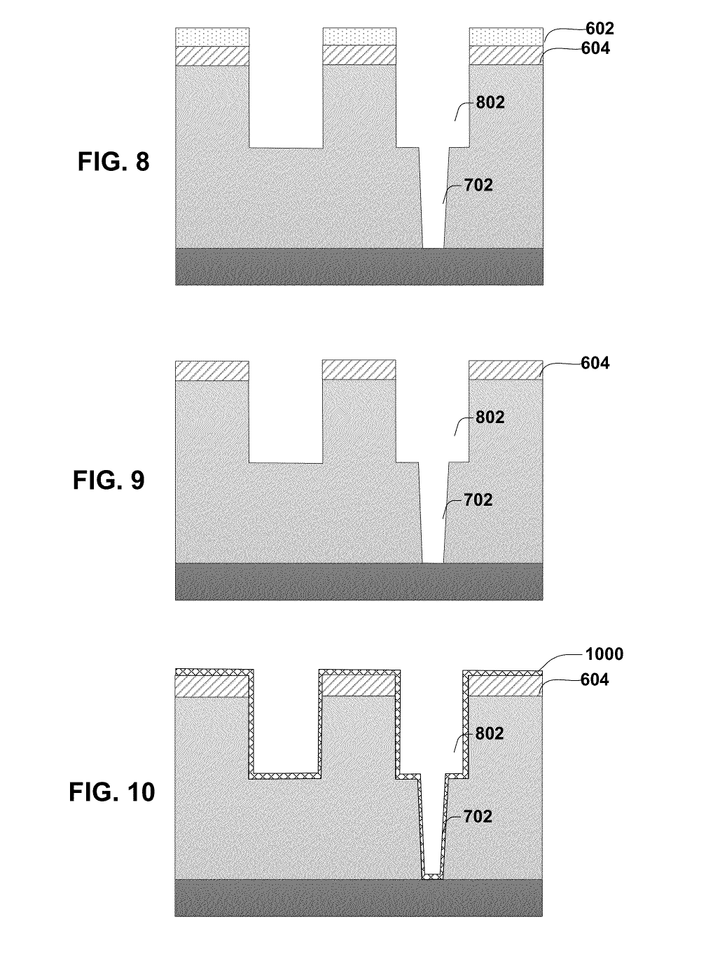

At FIG. 7 and FIG. 8, a typical via-first dual damascene process is shown. At FIG. 7, a via 702 is formed first. At FIG. 8, a trench 802 is applied next. The trench 802 and via 702 can be formed by any other interconnect etching method like trench-first or double patterning dual damascene approaches.

At FIG. 9, the hard mask layer 602 in FIG. 8 is removed by wet or dry etching.

At FIG. 10, a pore seal layer 1000 is applied. The pore seal layer is applied onto the via 702, the trench 802 and surface of the anti-reflection coating layer 604.

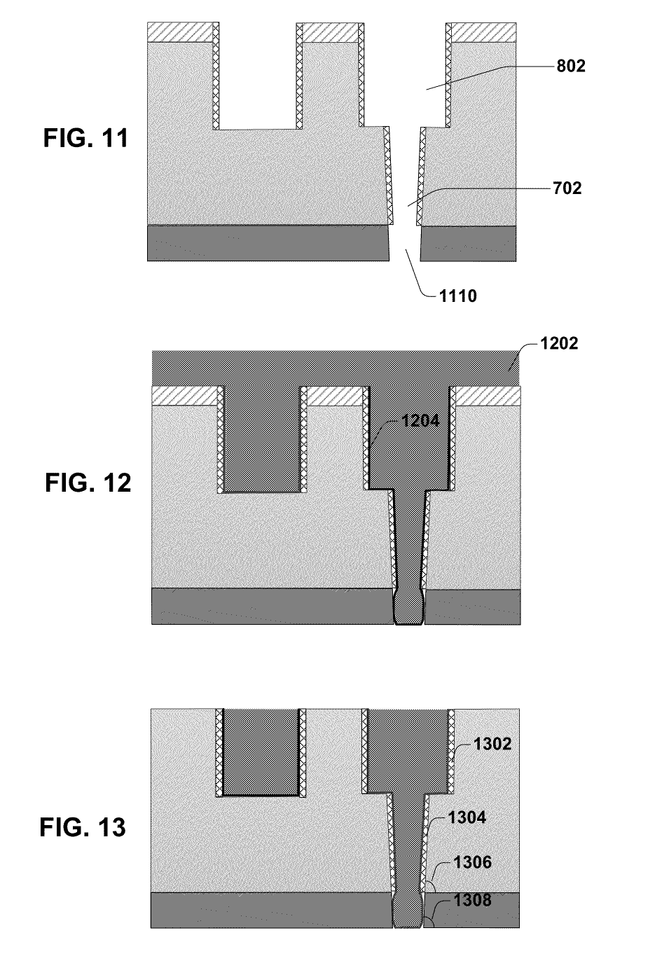

At FIG. 11, an etching and cleaning process is applied to remove both the etch stop layer portion 1110 and the pore seal layer on the bottom of the via 702. Therefore, no additional process and damage will be introduced by removing the pore seal layer. The etching needs to be highly anisotropic, wherein very little lateral etch is applied. This can be realized by lower pressure (smaller than 40 mTorr) and higher bias power (larger than 100 W). As a result, no pore seal material is applied to sidewall of the opening and critical dimension is less affected by the deposition of pore seal material compared to traditional method that pore seal material will be on the sidewall of the opening.

At FIG. 12, a conductive material 1202 and a barrier layer 1204 are applied to form a conductive interconnect structure.

At FIG. 13, Chemical-Mechanical polishing is applied to remove extra layers used for process above the porous low-k material. Thickness of pore seal on trench sidewalls 1302 may be different from pore seal on via sidewalls 1304. Depends on etching method at 414, the thickness of pore seal on trench sidewalls 1302 can be either larger or smaller than the thickness of pore seal on via sidewalls 1304.

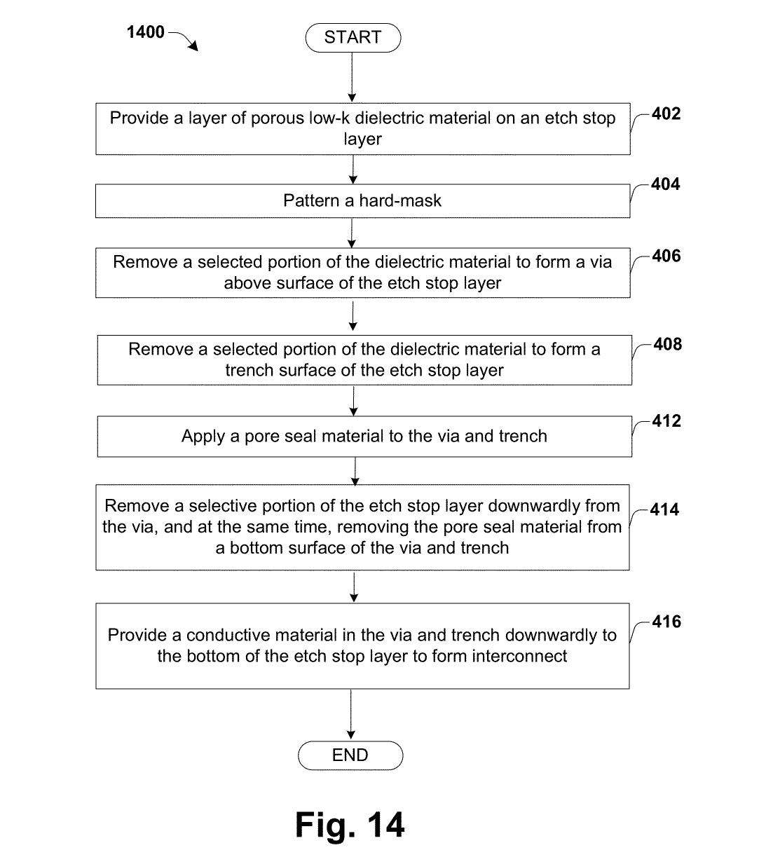

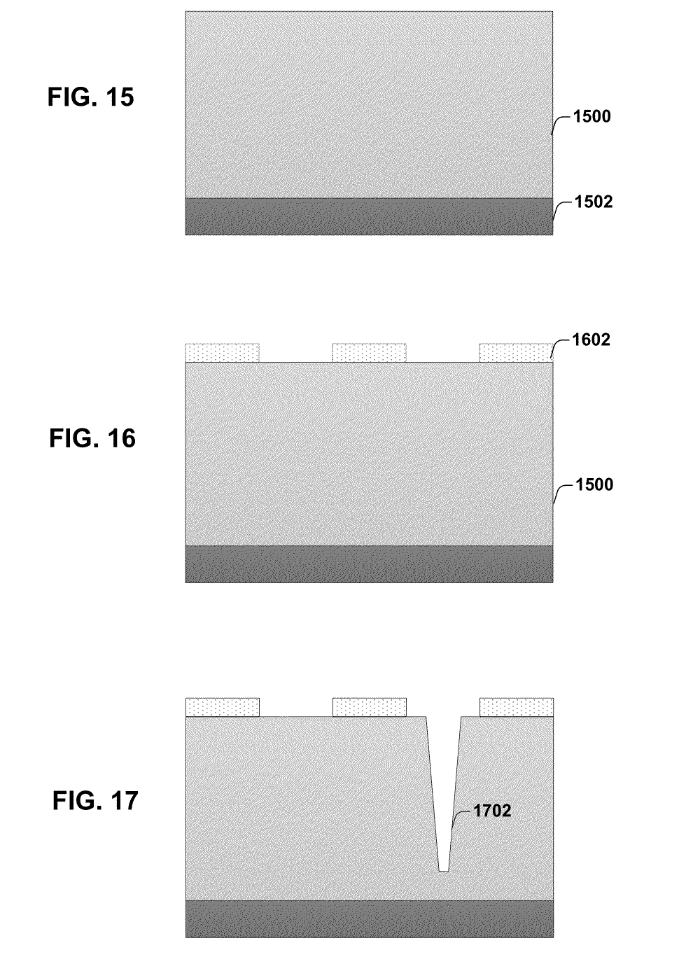

FIG. 14 illustrates a detailed flow diagram of some alternative embodiments of a method for forming a pore sealing layer. One example of FIG. 14's method is now described with regards to a series of cross-sectional views as shown in FIGS. 15-22. Besides the similarity to the process above, in these examples, some embodiments that pattern a hard mask 1602 (FIG. 16) and not remove it prior to applying a pore seal layer are shown.

At FIG. 15, a porous low-k material 1500 is applied onto the etch stop layer 1502.

At FIG. 16, a hard mask 1602 is patterned.

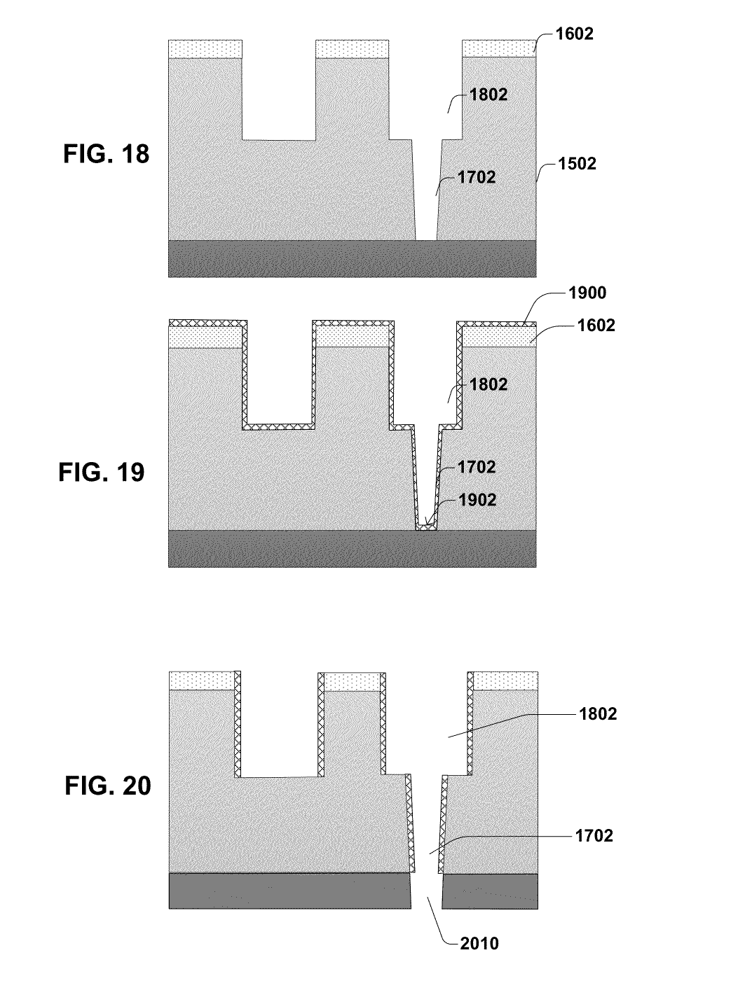

At FIG. 17 and FIG. 18, a dual damascene process is performed.

At FIG. 19, a pore seal layer 1900 is applied. The pore seal layer is applied onto the via 1702, the trench 1802 and surface of the hard mask layer 1602. Pore seal material on the bottom of the via 1902 will be removed in the next step.

At FIG. 20, an etching and cleaning process is applied to remove both the etch stop layer portion 2010 and the pore seal layer on the bottom of the via (1902 in FIG. 19).

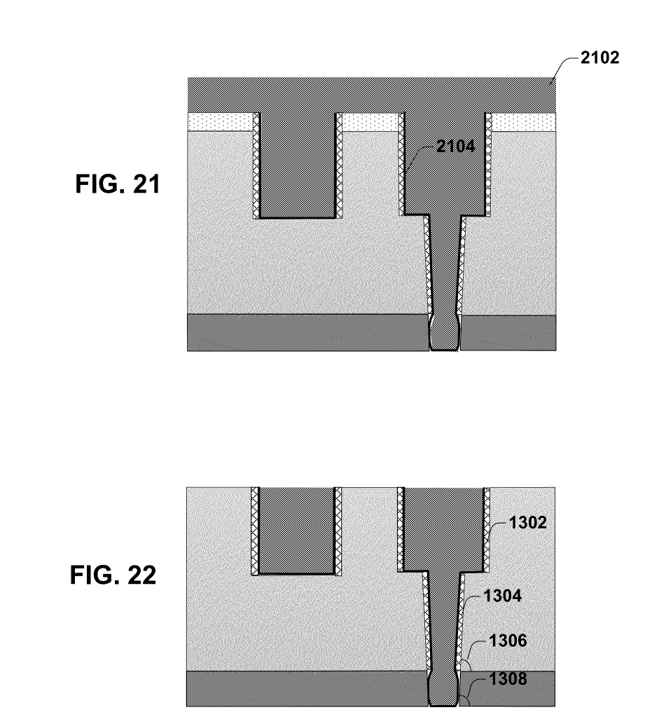

At FIG. 21, a conductive material is applied to form a conductive interconnect structure.

At FIG. 22, chemical-mechanical polishing is applied to remove extra layers used for process above the porous low-k material.

Thus, some embodiments relate to a semiconductor device. The device includes a first conductive layer, and an etch stop layer (ESL) over the first conductive layer. A porous low-k dielectric layer is formed over the ESL layer. An opening extends downwardly through both the porous low-k dielectric layer and the ESL and stops at the first conductive layer. The opening defines both a dielectric sidewall in the porous low-k dielectric layer and an ESL sidewall in the ESL. A pore seal layer is disposed on the dielectric sidewall but does not cover the ESL sidewall. A conductive material is formed over the pore seal layer. The conductive material fills the opening to form an interconnect structure to a second conductive layer over the porous low-k dielectric layer.

Other embodiments relate to a semiconductor device. The semiconductor device includes first and second conductive layers over a semiconductor substrate. A porous low-k dielectric material is arranged between the first and second conductive layers and includes a trench and a via disposed therein. The trench includes trench sidewalls extending downwardly from the second conductive layer to a trench bottom surface. The via includes via sidewalls extending downwardly from the trench bottom surface to the first conductive layer. The via sidewalls are more closely spaced than the trench sidewalls. A pore seal material is disposed on the trench sidewalls and disposed on an upper region of the via sidewalls near the porous low-k dielectric layer, but is not disposed on a lower region of the via sidewalls near the first conductive layer. A conductive material is formed over the pore seal material and fills the trench and via to electrically couple the first and second conductive layers to one another.

Still another embodiment relates to a method of forming a conductive interconnect structure on an integrated circuit die. In this method, a layer of porous low-k dielectric material is provided on an etch stop layer. A selected portion of the dielectric material is removed to form an opening therein. A pore seal layer is applied to the opening. A selective portion of the etch stop layer is removed downwardly from the opening, and concurrently, the pore seal material is removed from a bottom surface of the opening. A conductive material is provided in the opening downwardly to the bottom of the etch stop layer to form an interconnect structure.

It will be appreciated that while reference is made throughout this document to exemplary structures in discussing aspects of methodologies described herein (e.g., the structure presented in FIGS. 5-12, while discussing the methodology set forth in FIG. 4B), that those methodologies are not to be limited by the corresponding structures presented. Rather, the methodologies (and structures) are to be considered independent of one another and able to stand alone and be practiced without regard to any of the particular aspects depicted in the Figs. Additionally, layers described herein, can be formed in any suitable manner, such as with spin on, sputtering, growth and/or deposition techniques, etc.

Also, equivalent alterations and/or modifications may occur to those skilled in the art based upon a reading and/or understanding of the specification and annexed drawings. The disclosure herein includes all such modifications and alterations and is generally not intended to be limited thereby. For example, although the figures provided herein, are illustrated and described to have a particular doping type, it will be appreciated that alternative doping types may be utilized as will be appreciated by one of ordinary skill in the art.

In addition, while a particular feature or aspect may have been disclosed with respect to only one of several implementations, such feature or aspect may be combined with one or more other features and/or aspects of other implementations as may be desired. Furthermore, to the extent that the terms “includes”, “having”, “has”, “with”, and/or variants thereof are used herein, such terms are intended to be inclusive in meaning—like “comprising.” Also, “exemplary” is merely meant to mean an example, rather than the best. It is also to be appreciated that features, layers and/or elements depicted herein are illustrated with particular dimensions and/or orientations relative to one another for purposes of simplicity and ease of understanding, and that the actual dimensions and/or orientations may differ substantially from that illustrated herein.

1. A semiconductor device comprising:
a first conductive layer;
an etch stop layer (ESL) over the first conductive layer;
a porous low-k dielectric layer formed over the ESL layer;
an opening extending downwardly through both the porous low-k dielectric layer and the ESL and stopping at the first conductive layer, wherein the opening defines both a dielectric sidewall in the porous low-k dielectric layer and an ESL sidewall in the ESL;
a pore seal layer disposed on the dielectric sidewall but not covering the ESL sidewall; and
a conductive material formed over the pore seal layer and filling the opening to form an interconnect structure to a second conductive layer over the porous low-k dielectric layer.

2. The semiconductor device of claim 1, wherein the pore seal layer comprises oxide, SiC, SiCN, SiN, or SiOCH.

3. The semiconductor device of claim 1, wherein thickness of the pore seal layer is between 1 and 10 .

4. The semiconductor device of claim 1, wherein the conductive material is copper.

5. A semiconductor device comprising:
first and second conductive layers over a semiconductor substrate;
a porous low-k dielectric material arranged between the first and second conductive layers and including a trench and a via disposed therein, wherein the trench includes trench sidewalls extending downwardly from the second conductive layer to a trench bottom surface, and wherein the via includes via sidewalls extending downwardly from the trench bottom surface to the first conductive layer, the via sidewalls being more closely spaced than the trench sidewalls;
a pore seal material disposed on the trench sidewalls and disposed on an upper region of the via sidewalls near the porous low-k dielectric layer but not disposed on a lower region of the via sidewalls near the first conductive layer;
a conductive material formed over the pore seal material and filling the trench and via to electrically couple the first and second conductive layers to one another.

6. The semiconductor device of claim 5, further comprising:
an etch stop layer (ESL) between the first conductive layer and the porous low-k dielectric material.

7. The semiconductor device of claim 6, wherein the via extends downwardly through the ESL, such that the lower region of the via sidewalls without pore seal material thereon corresponds to ESL sidewalls adjacent to the via.

8. The semiconductor device of claim 5, wherein the via sidewall forms a first non-perpendicular angle with regards to an upper surface of the porous low-k dielectric material layer and forms a second non-perpendicular angle with regards to an upper surface of the ESL.

9. The semiconductor device of claim 8, wherein the first angle is different from the second angle.

10. The semiconductor device of claim 5, wherein a thickness of the pore seal material on the trench sidewalls is larger or smaller than a thickness of the pore seal layer on the via sidewalls.

11. A method of forming a pore sealing for conductive interconnect structure on an integrated circuit die, the method comprising:
providing a layer of porous low-k dielectric material on an etch stop layer;
removing a selected portion of the dielectric material to form an opening therein;
applying a pore seal layer to the opening;
removing a selective portion of the etch stop layer downwardly from the opening, and concurrently removing the pore seal material from a bottom surface of the opening; and
providing a conductive material in the opening downwardly to the bottom of the etch stop layer to form an interconnect structure.

12. The method according to claim 11, wherein a hard mask layer is patterned prior to the formation of the opening.

13. The method according to claim 12, the hard-mask layer is removed using wet or dry etching after the formation of the opening and prior to the deposition of pore seal layer.

14. The method according to claim 11, wherein the pore seal material is applied prior to the removal of the selected portion of the etch stop layer.

15. The method according to claim 11, wherein the removal of a selective portion of the etch stop layer and the pore seal material on the bottom of the opening is accomplished by a liner removal method wherein a bottom etch rate is larger than a sidewall etch rate.

16. The method according to claim 16, wherein the liner removal method etching is highly anisotropic, wherein a pressure lower than 40 mtorr and a bias power larger than 100 W are used.

17. The method according to claim 11, wherein the pore seal layer is applied by PECVD, CVD, ALD, PEALD, HDP, or Flowable CVD.

18. The method according to claim 11, wherein removing the selected portion of the dielectric material to form the opening comprises: forming a trench in the dielectric material and forming a via in the dielectric material under the trench.

19. The method according to claim 19, wherein the trench and the via are formed by a dual damascene method including via-first, trench first, or double patterning approach.

20. The method according to claim 11, wherein a chemical-mechanical polish is applied to remove a layer above the porous low-k layer top surface.
